(19) United States
(12) Patent Application Publication
(10) Pub. No.: US 2025/0108583 A1
(43) Pub. Date: Apr. 3, 2025

(54) COMPOSITE MATERIAL, APPLICATIONS THEREOF, AND METHOD FOR PRODUCING BASE MATERIAL TO WHICH POLYDOPAMINE IS ADHERED

(71) Applicant: Panasonic Intellectual Property Management Co., Ltd., Osaka (JP)

(72) Inventors: KAZUKI AITA, Osaka (JP); TERUHIKO SAITO, Osaka (JP); TEPPEI HOSOKAWA, Hyogo (JP); HONAMI INOBE, Osaka (JP)

(21) Appl. No.: 18/976,429

(22) Filed: Dec. 11, 2024

Related U.S. Application Data
(63) Continuation of application No. PCT/JP2023/020742, filed on Jun. 5, 2023.

(30) Foreign Application Priority Data
Jun. 30, 2022 (JP) 2022-106353

(51) Int. Cl. B32B 15/08

(52) U.S. Cl. CPC B32B 15/08; B32B 2264/107; B32B 2264/402; B32B 2307/206; B32B 2457/00

(57) ABSTRACT

A composite material includes a base material and polydopamine adhered to the base material. In an infrared absorption spectrum of the base material to which the polydopamine is adhered, the infrared absorption spectrum being obtained by Fourier transform infrared spectroscopy, a ratio H_{B}/H_{A} satisfies 0.66≤H_{B}/H_{A}≤1.1, where, in the infrared absorption spectrum, a baseline is defined as a straight line connecting a measured point obtained at 3070 cm⁻¹ to a measured point obtained at 3700 cm⁻¹, H_{A} represents a perpendicular distance from a measured point obtained at 3380 cm⁻¹ of the infrared absorption spectrum to the baseline, and H_{B} represents a perpendicular distance from a measured point obtained at 3630 cm⁻¹ of the infrared absorption spectrum to the baseline.

### BACKGROUND

### 1. Technical Field

The present disclosure relates to a composite material, applications thereof, and a method for producing a base material to which polydopamine is adhered.

### 2. Description of the Related Art

In the field of electronics, the level of performance required in electronic devices has been increasing in recent years as the utilization of 5th generation wireless systems (5G) is expanding. For example, a higher frequency band is used in 5G technology to achieve a higher communication speed than those of past generations. Accordingly, electronic devices need to include a high-frequency-compatible wiring board.

In the transmission line of wiring boards, transmission loss depends on the frequency, that is, the higher the frequency of the signal, the greater the transmission loss. The transmission loss depends on a relative dielectric constant and a dielectric loss tangent. Accordingly, the substrate material that forms the insulating layer of a wiring board needs to have a low relative dielectric constant and a low dielectric loss tangent so that the transmission loss of high-frequency signals can be reduced. In particular, when the frequency is in a high-frequency band, the dielectric loss tangent greatly depends on the orientation polarization of organic molecules present in the substrate material. Accordingly, a reduction in the amount of polar groups present in the substrate material, such as hydroxy groups and amino groups, is needed.

Furthermore, in the case of high-capacity communications, such as those realized by the 5G technology, the radio wave transmission distance is short because of the use of a high-frequency band. Accordingly, the power of electronic devices needs to be increased. In addition, achieving a high degree of integration and miniaturization requires increasing the packaging density of the circuit. Satisfying these needs results in an increase in the amount of heat generated per unit area of the wiring board. Accordingly, wiring boards need to have enhanced heat dissipation properties. An approach commonly used to enhance the heat dissipation properties of a wiring board is to include a filler (filling material) having excellent thermal conductivity, in the substrate material that constitutes the insulating layer of the wiring board, thereby increasing the thermal conductivity of the wiring board.

### SUMMARY

In one general aspect, the techniques disclosed here feature a composite material including a base material and polydopamine adhered to the base material. In an infrared absorption spectrum of the base material to which the polydopamine is adhered, the infrared absorption spectrum being obtained by Fourier transform infrared spectroscopy, a ratio H_{B}/H_{A} satisfies 0.66≤H_{B}/H_{A}≤1.1, where, in the infrared absorption spectrum, a baseline is defined as a straight line connecting a measured point obtained at 3070 cm⁻¹ to a measured point obtained at 3700 cm⁻¹, H_{A} represents a perpendicular distance from a measured point obtained at 3380 cm⁻¹ of the infrared absorption spectrum to the baseline, and H_{B} represents a perpendicular distance from a measured point obtained at 3630 cm⁻¹ of the infrared absorption spectrum to the baseline.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram illustrating a schematic configuration of a composite material according to a first embodiment;

FIG. 2 is an example of an infrared absorption spectrum of the composite material according to the first embodiment;

FIG. 3 is an enlarged view of main parts of the infrared absorption spectrum of FIG. 2;

FIG. 4 is a flowchart illustrating an example of a method for producing the composite material according to the first embodiment;

FIG. 5 is a diagram illustrating a schematic configuration of a resin composition according to a fourth embodiment;

FIG. 6 is a cross-sectional view of a resin-equipped film according to a sixth embodiment;

FIG. 7 is a cross-sectional view of a resin-equipped metal foil according to a seventh embodiment;

FIG. 8 is a cross-sectional view of a metal-clad laminate according to an eighth embodiment;

FIG. 9 is a cross-sectional view of a wiring board according to a ninth embodiment;

FIG. 10 shows infrared absorption spectra of Examples 1, 2, 7, and 8 and Comparative Example 1;

FIG. 11A is an enlarged view of a main part of the infrared absorption spectrum of Example 1;

FIG. 11B is an enlarged view of a main part of the infrared absorption spectrum of Example 2;

FIG. 11C is an enlarged view of a main part of the infrared absorption spectrum of Example 7;

FIG. 11D is an enlarged view of a main part of the infrared absorption spectrum of Example 8; and

FIG. 12 is a N 1s spectrum obtained by XPS in Example 2.

### DETAILED DESCRIPTIONS

### Underlying Knowledge Forming Basis of the Present Disclosure

If the heat dissipation properties of a wiring board are enhanced by increasing a content of a filler in a resin composition, mechanical properties such as flexibility are impaired, which is likely to result in embrittlement of the insulating layer. A possible reason for this is the aggregation of the filler in the resin composition. An effective way to improve dispersibility while inhibiting the aggregation of the filler is to chemically modify a surface of the filler.

Boron nitride is a material having high thermal conductivity, excellent heat dissipation properties, and excellent electrically insulating properties. Accordingly, boron nitride has attracted attention for its use as a filler in the insulating layer of wiring boards (e.g., Japanese Unexamined Patent Application Publication No. 2018-043899). It should be noted, however, that boron nitride particles do not have many functional groups present on their surface, and, therefore, most of the surface is inactive. Accordingly, it is difficult to improve the dispersibility of boron nitride particles in the resin composition by directly treating the surface of the particles by using a method such as silane coupling.

It is to be noted that a dopamine-containing protein secreted from the byssus gland of mussels, which are a type of bivalve, exhibits a stable adhesive strength even in sea water and thus is known as a naturally occurring adhesive. According to Haeshin Lee, Shara M. Dellatore, William M. Miller, Phillip B. Messersmith, Science, 2007, vol. 318, pp. 426-430, when a substrate is immersed in a dopamine solution, the dopamine undergoes self-oxidative polymerization to form a polydopamine thin film on a surface of the substrate. Heng Shen, Jing Guo, Hao Wang, Ning Zhao, Jian Xu, ACS Appl. Mater. Interfaces, 2015, 7, pp. 5701-5708 states that this feature was utilized to improve the dispersibility of boron nitride as a filler, by coating the boron nitride with polydopamine. Katerina G. Malollari, Peyman Delparastan, Caroline Sobek, Shraddha J. Vachhani, Tanner D. Fink, R. Helen Zha, Phillip B. Messersmith, Mechanical Enhancement of Bioinspired Polydopamine Nanocoatings, ACS Appl. Mater. Interfaces, 2019, 11, pp. 43599-43607 states that polydopamine is heat-treated at 130° C.

It should be noted that, since polydopamine has a large number of hydroxy groups, polydopamine has a feature of readily adsorbing moisture from the air, which is a feature called hydrophilicity. Accordingly, in an instance where boron nitride to which polydopamine is adhered is used as a filler, there is a concern that a dielectric loss tangent may deteriorate.

The present inventors diligently conducted studies to reduce the dielectric loss tangent of a base material. As a result, they arrived at a composite material of the present disclosure.

Overview of Aspects of the Present Disclosure According to a first aspect of the present disclosure, a composite material includes
a base material; and
polydopamine adhered to the base material.

In an infrared absorption spectrum of the base material to which the polydopamine is adhered, the infrared absorption spectrum being obtained by Fourier transform infrared spectroscopy, a ratio H_{B}/H_{A} satisfies 0.66≤H_{B}/H_{A}≤1.1, where, in the infrared absorption spectrum, a baseline is defined as a straight line connecting a measured point obtained at 3070 cm⁻¹ to a measured point obtained at 3700 cm⁻¹, H_{A} represents a perpendicular distance from a measured point obtained at 3380 cm⁻¹ of the infrared absorption spectrum to the baseline, and H_{B} represents a perpendicular distance from a measured point obtained at 3630 cm⁻¹ of the infrared absorption spectrum to the baseline.

With this configuration, the composite material can have a low dielectric loss tangent.

In a second aspect of the present disclosure, the composite material according to the first aspect may be one in which, for example, the ratio H_{B}/H_{A} satisfies 0.70≤H_{B}/H_{A}≤0.90. With this configuration, the composite material can have a lower dielectric loss tangent.

In a third aspect of the present disclosure, the composite material according to the first or second aspect may be one in which, for example, in a N 1s spectrum of the composite material, the N 1s spectrum being obtained by X-ray photoelectron spectroscopy, a ratio of an area of a peak corresponding to a nitrogen atom of a primary amino group to an area of an entirety of the N 1s spectrum is greater than or equal to 3.0% and less than or equal to 7.0%. With this configuration, the composite material can have a lower dielectric loss tangent.

In a fourth aspect of the present disclosure, the composite material according to any one of the first to third aspects may be one in which, for example, the base material includes at least one selected from the group consisting of boron nitride, aluminum nitride, silicon nitride, aluminum oxide, magnesium oxide, and silica. The composite material of the present disclosure is particularly useful when the base material includes at least one selected from the above-mentioned group.

In a fifth aspect of the present disclosure, the composite material according to the fourth aspect may be one in which, for example, the base material includes boron nitride. The composite material of the present disclosure is particularly useful when the base material includes boron nitride.

According to a sixth aspect of the present disclosure, a filler includes the composite material according to any one of the first to fifth aspects. With this configuration, the filler can have a low dielectric loss tangent.

According to a seventh aspect of the present disclosure, a resin composition includes the filler of the sixth aspect. With regard to the seventh aspect, the resin composition can exhibit a low dielectric loss tangent and have excellent thermal stability.

According to an eighth aspect of the present disclosure, a prepreg includes the resin composition according to the seventh aspect or a semi-cured product of the resin composition.

According to a ninth aspect of the present disclosure, a resin-equipped film includes
a resin layer including the resin composition according to the seventh aspect or including a semi-cured product of the resin composition; and
a support film.

According to a tenth aspect of the present disclosure, a resin-equipped metal foil includes
a resin layer including the resin composition according to the seventh aspect or including a semi-cured product of the resin composition; and
a metal foil.

According to an eleventh aspect of the present disclosure, a metal-clad laminate includes
an insulating layer including a cured product of the resin composition according to the seventh aspect or including a cured product of a prepreg, the prepreg including the resin composition or including a semi-cured product of the resin composition; and
a metal foil.

According to a twelfth aspect of the present disclosure, a wiring board includes
an insulating layer including a cured product of the resin composition according to the seventh aspect or including a cured product of a prepreg, the prepreg including the resin composition or including a semi-cured product of the resin composition; and
a wiring.

With regard to the eighth to twelfth aspects, various applications suitable for use with high frequencies can be provided.

According to a thirteenth aspect of the present disclosure, a method for producing a base material to which polydopamine is adhered includes
causing polydopamine to be adhered to a surface of a base material; and
heating the base material and the polydopamine adhered to the surface.

With this configuration, it is possible to produce a base material to which polydopamine is adhered that has a low dielectric loss tangent.

In a fourteenth aspect of the present disclosure, the method for producing a base material to which polydopamine is adhered according to the thirteenth aspect may be one in which, for example, the heating includes heating the base material and the polydopamine at a temperature of greater than or equal to 100° C. and less than or equal to 400° C. With this configuration, the base material to which polydopamine is adhered has a lower dielectric loss tangent.

In a fifteenth aspect of the present disclosure, the method for producing a base material to which polydopamine is adhered according to the thirteenth aspect may be one in which, for example, the heating includes heating the base material and the polydopamine at a temperature of greater than or equal to 200° C. and less than or equal to 300° C. With this configuration, the base material to which polydopamine is adhered has an even lower dielectric loss tangent.

Embodiments of the present disclosure will be described below with reference to the drawings.

### First Embodiment

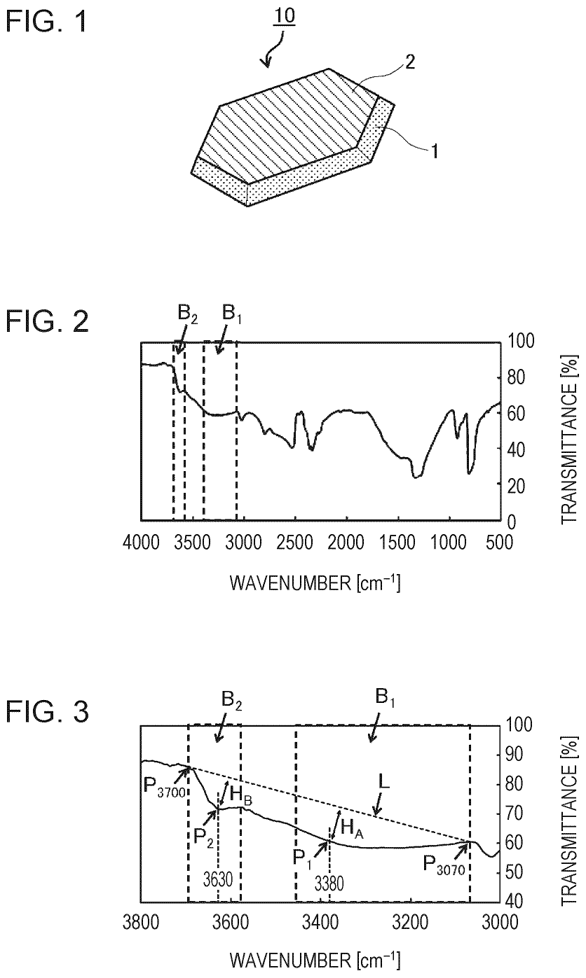

A first embodiment will be described below with reference to FIGS. 1 to 4.

### Composite Material

FIG. 1 is a diagram illustrating a schematic configuration of a composite material 10, according to the first embodiment. The composite material 10 includes a base material 1 and polydopamine 2.

The polydopamine 2 may be adhered to a surface of the base material 1. Specifically, the polydopamine 2 may be adhered to the surface of the base material 1 as a result of chemical modification of the surface of the base material 1 with the polydopamine 2. The polydopamine 2 may coat at least a portion of the surface of the base material 1. The polydopamine 2 may coat the entire surface of the base material 1 or only a portion of the surface of the base material 1.

In an infrared absorption spectrum of the composite material 10, a baseline L is defined as a straight line connecting a measured point P₃₀₇₀, which is a point obtained at 3070 cm⁻¹, and a measured point P₃₇₀₀, which is a point obtained at 3700 cm⁻¹. In the composite material 10, a ratio H_{B}/H_{A} satisfies 0.66≤H_{B}/H_{A}≤1.1. H_{A} represents a perpendicular distance from a measured point P₁, which is a point obtained at 3380 cm⁻¹ of the infrared absorption spectrum, to the baseline L, and H_{B} represents a perpendicular distance from a measured point P₂, which is a point obtained at 3630 cm⁻¹ of the infrared absorption spectrum, to the baseline L. The infrared absorption spectrum is a spectrum obtained by Fourier transform infrared spectroscopy (FT-IR) in a diffuse reflection mode.

FIG. 2 shows an example of an infrared absorption spectrum of the composite material 10. In the drawings of the present application, the infrared absorption spectra are shown by plotting a transmittance (%) on the vertical axis. FIG. 2 shows an example in which boron nitride is used as the base material 1. FIG. 3 is an enlarged view of main parts of the infrared absorption spectrum of FIG. 2. As shown in FIG. 3, a first absorption band B₁ is defined as a range of greater than or equal to 3070 cm⁻¹ and less than or equal to 3450 cm⁻¹, and a second absorption band B₂ is defined as a range of greater than or equal to 3580 cm⁻¹ and less than or equal to 3680 cm⁻¹, in the infrared absorption spectrum. The first absorption band B₁ and the second absorption band B₂ have respective local minimum values of the transmittance in their respective ranges.

The transmittance in the vicinity of the measured point P₁ in the first absorption band B₁ depends on the amount of hydrogen-bond-forming hydroxy groups that are present in the coating film made of the polydopamine 2. For example, as the amount of hydrogen-bond-forming hydroxy groups that are present in the coating film made of the polydopamine 2 decreases, the transmittance in the vicinity of the measured point P₁ in the first absorption band B₁ increases. Accordingly, the value of H_{A} reflects the amount of hydrogen-bond-forming hydroxy groups that are present in the coating film made of the polydopamine 2. The transmittance in the vicinity of the measured point P₂ in the second absorption band B₂ depends on the amount of hydroxyl radicals that are present in the coating film made of the polydopamine 2. For example, as the amount of hydroxyl radicals that are present in the coating film made of the polydopamine 2 decreases, the transmittance in the vicinity of the measured point P₂ in the second absorption band B₂ increases. Accordingly, the value of H_{B} reflects the amount of hydroxyl radicals that are present in the coating film made of the polydopamine 2. Accordingly, the H_{B}/H_{A} is a parameter that defines the relationship between the amount of hydrogen-bond-forming hydroxy groups that are present in the coating film made of the polydopamine 2 and the amount of hydroxyl radicals that are present in the coating film made of the polydopamine 2, as a ratio of the perpendicular distance from the measured point P₂ of the second absorption band B₂ to the baseline L to the perpendicular distance from the measured point P₁ of the first absorption band B₁ to the baseline L. For example, in the example of FIG. 3, the H_{B}/H_{A} is 0.815.

The present inventors discovered that in instances where the ratio H_{B}/H_{A} of the composite material 10 satisfies 0.66≤H_{B}/H_{A}≤1.1, a reduction in the dielectric loss tangent is achieved. In a heat treatment, which will be described later, when a heat treatment temperature is increased, the amount of hydroxyl radicals present in the coating film made of the polydopamine 2 decreases, and as a result, the dielectric loss tangent is reduced. That is, the greater the H_{B}/H_{A}, the greater the tendency for the dielectric loss tangent to decrease. However, if the heat treatment temperature is excessively high, the dielectric loss tangent begins to increase. That is, when the H_{B}/H_{A} is excessively high, there is a tendency for the dielectric loss tangent to increase. Presumably, this is because an excessively high heat treatment temperature results in the progression of collapse of the ring structure (an indoline skeleton and/or indole skeleton) of the polydopamine 2.

In the composite material 10, the ratio H_{B}/H_{A} may satisfy 0.70≤H_{B}/H_{A}≤0.90. With this configuration, the composite material 10 has a lower dielectric loss tangent.

In a N 1s spectrum of the composite material 10, a ratio R₁, which is a ratio of an area of a peak corresponding to the nitrogen atom of a primary amino group to an area of the entirety of the N 1s spectrum, may be greater than or equal to 3.0% and less than or equal to 7.0%. The N 1s spectrum is a spectrum obtained by X-ray photoelectron spectroscopy (XPS).

XPS is a method for analyzing the constituent elements of a sample and their electronic states by irradiating a surface of the sample with X-rays and measuring the energy of generated photoelectrons. The state of the chemical bond of the nitrogen in the composite material 10 can be measured by XPS. Specifically, in the N 1s spectrum measured by XPS, a peak referred to as N 1s can be obtained because of photoelectrons derived from nitrogen atoms present on the surface of the sample. In the N 1s spectrum, the vertical axis represents an intensity (AU) of the spectrum, and the horizontal axis represents a binding energy (eV). The N 1s spectrum is a synthesis of various peaks, which vary depending on the bonding state of the nitrogen atoms present on the surface of the sample. The positions of the various peaks depend on the state of the chemical bonding of the nitrogen atoms. A peak P₁ is defined as a peak corresponding to the nitrogen atom of a primary amino group. In the N 1s spectrum, the peak P₁ appears around 402 eV, for example.

The ratio R₁ can be determined in the following manner. First, the obtained N 1s spectrum is separated into the peak P₁ and the other peaks. The area of each of the peaks is calculated. The ratio R₁ can be determined by calculating a proportion of the area of the peak P₁ to the sum of the areas. The separation of the peak P₁ from the other peaks can be carried out in the following manner. The N 1s spectrum obtained by XPS appears in a binding energy range of the N 1s electrons of the nitrogen atoms (around 396 to 404 eV). It is presumed that three components, namely, ═N—R, R₂—NH, and R—NH₂, are present in the composite material 10. The peaks of these components overlap one another, and a technique that can be used for separating the peaks of the components is as follows: the peak of each of the components is approximated with the Gaussian-Lorentzian mixed function, and then, fitting is performed by using, as parameters, a peak intensity, a peak position, and a peak full width at half maximum.

The polydopamine 2 may have an indoline skeleton and/or an indole skeleton as will be described later (see formula (1) below). The polydopamine 2 may include a unit that is not fully cyclized. That is, the polydopamine 2 may include both a primary amine and a secondary amine. Regarding the composite material 10, the heat treatment, which will be described later, allows the primary amine to contribute to the cyclization and crosslinking between polydopamine molecules, and as a result, the polydopamine has a stabilized structure. Accordingly, in the composite material 10, the number of primary amines is reduced, whereas the number of secondary amines is increased. Furthermore, the primary amine reacts with the hydroxy group present in the polydopamine to form an imine bond (C═N), and as a result, the number of hydroxy groups is reduced. Accordingly, the dielectric loss tangent of the composite material 10 is further reduced.

In the present embodiment, the ratio R₁ may satisfy 3.5%≤R₁≤6.5% or satisfy 3.9%≤R₁≤5.8%. In these cases, the dielectric loss tangent is further reduced.

### Base Material

The base material 1 may include at least one selected from the group consisting of boron nitride, aluminum nitride, silicon nitride, aluminum oxide, magnesium oxide, and silica. The composite material 10 is particularly useful when the base material 1 includes at least one selected from the mentioned group.

The base material 1 may include boron nitride. The composite material 10 is particularly useful when the base material 1 includes boron nitride. Boron nitride has excellent thermal conductivity and, therefore, is used, for example, as a filler. The base material 1 may be boron nitride.

Examples of boron nitride that can be used include hexagonal boron nitride (h-BN) having a graphite-type lamellar structure, diamond-type cubic boron nitride (c-BN), and amorphous boron nitride (a-BN). Hexagonal boron nitride is particularly useful because it can be synthesized relatively easily and has the features of excellent thermal conductivity, electrically insulating properties, chemical stability, and thermal stability. The boron nitride that is used may be boron nitride particles. Typically, the boron nitride particles have a white color. The boron nitride particles may have any shape. Examples of the shape of the boron nitride particles include flake shapes, spherical shapes, ellipsoidal shapes, and rod shapes.

The boron nitride particles may have any average particle size. For example, the average particle size of the boron nitride particles may be greater than or equal to 0.05 μm and less than or equal to 100 μm or may be greater than or equal to 0.1 μm and less than or equal to 50 μm. In the present disclosure, the average particle size of the boron nitride particles is a median size. The median size is a particle size (d50) corresponding to a cumulative volume of 50% in a volume-based particle size distribution. The volume-based particle size distribution is measured, for example, by using a laser diffraction analyzer.

### Polydopamine

The polydopamine 2 is a polymer of dopamine and may, for example, have one or both of the two types of repeating units represented by formula (1) below. Note that in formula (1) below, the portion having an indoline skeleton may instead have an indole skeleton.

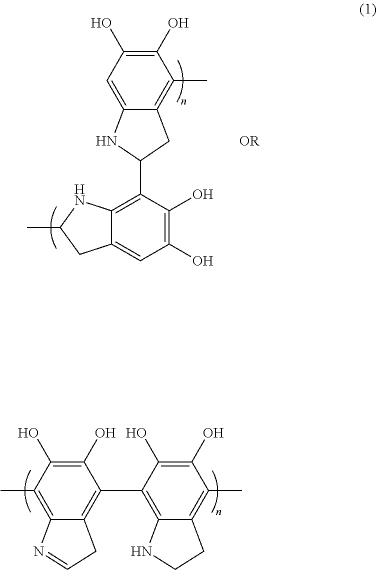

In formula (1), n is an integer greater than or equal to 1. In formula (1), n may be an integer greater than or equal to 2.

The polydopamine 2 may have a shape of a thin film on the surface of the base material 1. The thin film made of the polydopamine 2 may have a thickness of, for example, 1 nm to 300 nm. The thin film made of the polydopamine 2 coats at least a portion of the surface of the base material 1. The thin film made of the polydopamine 2 may coat the entirety of the surface of the base material 1, as illustrated in FIG. 1.

The presence of the polydopamine 2 on the base material 1 can be confirmed by a dark brown color exhibited by the surface of the base material 1.

Regarding the polymer, even if a dopamine-derived functional group is partially changed by the heat treatment, the polymer is regarded as “polydopamine” in the present specification. An example of the change in the functional group is the elimination of hydroxy groups resulting from the heat treatment of the polydopamine.

### Method for Producing Composite Material

Now, a method for producing the above-described composite material 10 will be described.

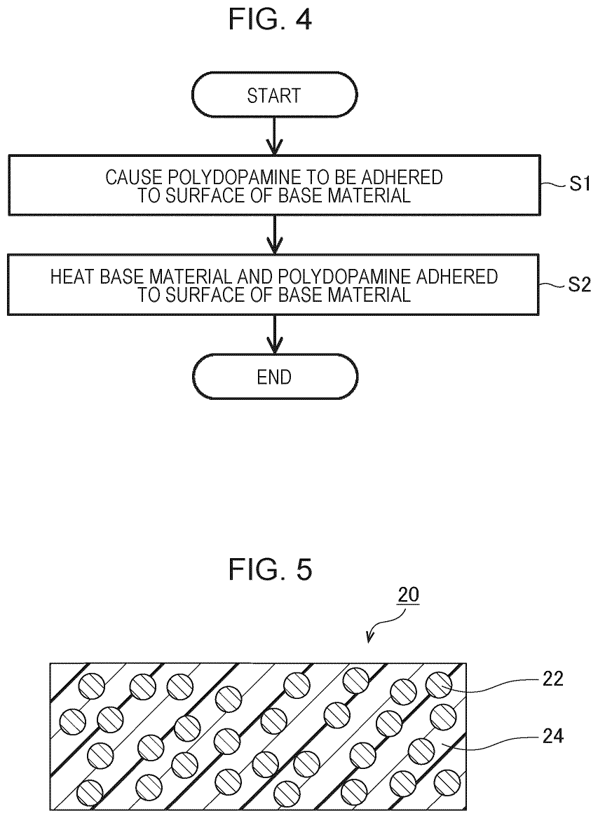

FIG. 4 is a flowchart illustrating an example of the method for producing the composite material 10. The method for producing the composite material 10 includes causing the polydopamine 2 to be adhered to the surface of the base material 1 (step S1) and heating the base material 1 and the polydopamine 2 adhered to the surface of the base material 1 (step S2).

In step S1, the polydopamine 2 is caused to be adhered to the surface of the base material 1 by utilizing self-oxidative polymerization of dopamine. Specifically, the base material 1 is contacted with a dopamine solution to cause oxidative polymerization of the dopamine, thereby causing the polydopamine 2 to be adhered to the surface of the base material 1. In this manner, a thin film made of the polydopamine 2 can be formed.

The dopamine solution can be obtained by adding dopamine hydrochloride to a Tris-HCl solution that has a pH adjusted to 8.5 and then stirring the solution. The dopamine solution may have any concentration, which may be, for example, within a range of 0.01 mg/mL to 30 mg/mL. The dopamine solution has a pH within a range of 6 to 11 or may have a pH within a range of 8 to 10. The pH of the dopamine solution can be adjusted by mixing a Tris-HCl solution or the like. During the oxidative polymerization, the dopamine solution has a temperature of, for example, 10° C. to 100° C. A polymerization time is, for example, 1 hour to 48 hours. The thin film made of the polydopamine 2 has a thickness of, for example, 1 nm to 300 nm. The thickness of the thin film made of the polydopamine 2 can be controlled by the polymerization time.

In step S2, the base material 1 and the polydopamine 2 adhered to the surface of the base material 1 are heated. Accordingly, the composite material 10 can be obtained.

The heating may be performed by any method. A heat treatment device known in the art, such as a sintering device, an electric furnace, or a hot plate, may be used to carry out the heating. It is desirable to use a sintering device or an electric furnace for the heating because in this case, temperatures can be easily adjusted.

In step S2, the heating may be performed such that an ambient temperature of the base material 1 reaches a range of greater than or equal to 100° C. and less than or equal to 400° C. or such that the ambient temperature of the base material 1 reaches a range of greater than or equal to 200° C. and less than or equal to 300° C. In step S2, the heating may be performed such that the ambient temperature of the base material 1 reaches a range of greater than or equal to 220° C. and less than or equal to 260° C. When the heating temperature is greater than or equal to 100° C., it is possible to sufficiently reduce the amounts of hydroxy groups and adsorbed water that are present in the polydopamine 2. When the heating temperature is less than or equal to 400° C., it is possible to inhibit the alteration of the structure of the polydopamine 2.

A heating time is, for example, greater than or equal to 1 hour and less than or equal to 48 hours. The heating time may be greater than or equal to 5 hours and less than or equal to 40 hours or may be greater than or equal to 10 hours and less than or equal to 30 hours. When the heating time is greater than or equal to 5 hours, it is possible to sufficiently remove hydroxy groups and adsorbed water that are present in the polydopamine 2. When the heating time is less than or equal to 40 hours, it is possible to inhibit a reduction in productivity and an increase in costs.

Regarding wiring boards, when the frequency is in a high-frequency band ranging from GHz to THz frequencies, the dielectric loss tangent greatly depends on the orientation polarization of organic molecules that are present in a material of the wiring boards. The hydroxy group of the polydopamine 2 can increase the dielectric loss tangent. In the composite material 10, however, the number of hydroxy groups in the polydopamine 2 is reduced as a result of the heat treatment, and, consequently, the composite material 10 can have a low dielectric loss tangent.

### Second Embodiment

According to a second embodiment, a thermally conductive gap filler includes the composite material 10 of the first embodiment.

In the present disclosure, a “thermally conductive gap filler” is a filler that is used to dissipate heat from electronic components by being applied to electronic components, such as a substrate material, to fill an air pocket, a space, or the like. The thermally conductive gap filler is a curable thermally conductive paste that is in a paste form and cures to have a sheet form. The thermally conductive gap filler of the present embodiment can have improved thermal stability.

The thermally conductive gap filler of the present embodiment can be produced, for example, by kneading the composite material 10 of the first embodiment with an epoxy resin, a silicone-containing resin, a silicone-free acrylic resin, or a ceramic resin.

### Third Embodiment

According to a third embodiment, a filler for a thermally conductive grease includes the composite material 10 of the first embodiment.

In the present disclosure, a “filler for a thermally conductive grease” is a filler for use in a thermally conductive grease. The thermally conductive grease is a non-curing, thermally conductive paste that is used to dissipate heat from electronic components by being applied to electronic components, such as a substrate material, to fill an air pocket, a space, or the like. The filler for a thermally conductive grease of the present embodiment can improve the thermal stability of fillers.

The filler for a thermally conductive grease of the present embodiment can be produced, for example, by kneading the composite material 10 of the first embodiment with an epoxy resin, a silicone-containing resin, a silicone-free acrylic resin, or a ceramic resin.

### Fourth Embodiment

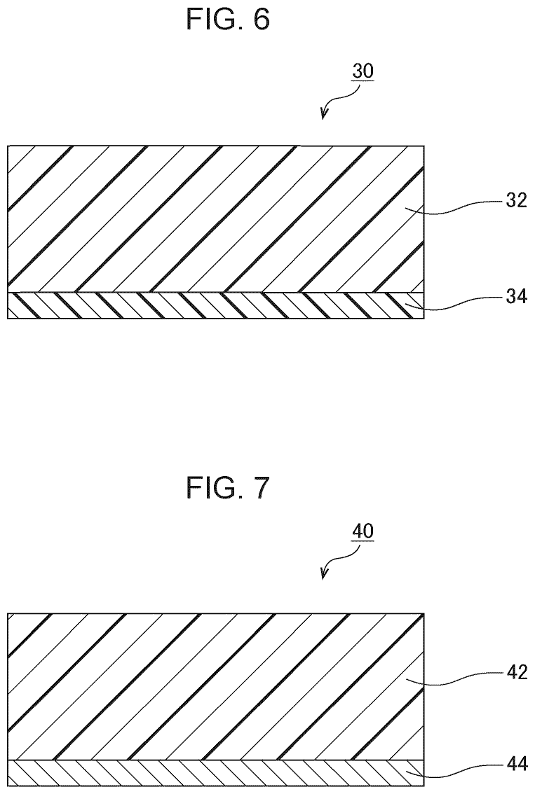

FIG. 5 is a diagram illustrating a schematic configuration of a resin composition 20, according to a fourth embodiment. The resin composition 20 includes, for example, a filler 22 and a curable resin 24.

The filler 22 includes the composite material 10, which is described above in the first embodiment. According to the present embodiment, the resin composition 20 exhibits a low dielectric loss tangent and has excellent thermal stability. The filler 22 may be composed entirely of the composite material 10 or may include one or more different filler materials, such as silica particles, in addition to the composite material 10.

Examples of the curable resin 24 include epoxy resins, cyanate ester compounds, maleimide compounds, phenolic resins, acrylic resins, polyamide resins, polyamide-imide resins, thermosetting polyimide resins, and polyphenylene ether resins. The curable resin 24 may be one of these or a combination of two or more of these.

The resin composition 20 may include one or more additional components.

Examples of the additional components include curing agents, flame retardants, UV absorbers, antioxidants, reaction initiator, silane coupling agents, fluorescent brightening agents, photosensitizers, dyes, pigments, thickeners, lubricants, defoaming agents, dispersants, leveling agents, brighteners, antistatic agents, polymerization inhibitors, and organic solvents. One of these or a combination of two or more of these may be used if necessary.

### Fifth Embodiment

According to a fifth embodiment, a prepreg includes the resin composition 20 of the fourth embodiment, illustrated in FIG. 5, or a semi-cured product thereof and also includes a fibrous base material. The fibrous base material is present in a matrix of the resin composition 20 or of the semi-cured product. The prepreg is a composite material composed of the resin composition 20 and the fibrous base material. According to the present embodiment, the prepreg is suitable for high-frequency-compatible wiring boards.

In the present embodiment, the semi-cured product is a material in which the resin composition 20 has been incompletely cured so that further curing can take place. That is, the semi-cured product is a material in a state in which the resin composition 20 has been partially cured. When the resin composition 20 is heated, for example, a viscosity thereof gradually decreases. When the heating is continued, curing commences subsequently, and the viscosity gradually increases. In such instances, the partially cured state may be a state of the resin composition 20 during a period lasting from when the viscosity begins to increase until the resin composition 20 completely cures.

The fibrous base material may be a material known in the art that is used in various laminates for an electrically insulating material. Examples of the fibrous base material include glass cloths, aramid cloths, polyester cloths, nonwoven glass fabrics, nonwoven aramid fabrics, nonwoven polyester fabrics, pulp paper, and linter paper.

The resin composition 20 is impregnated into the fibrous base material by a treatment such as immersion or application. Heating the fibrous base material, which has been impregnated with the resin composition 20, under predetermined heating conditions gives the prepreg of the present embodiment that is in a pre-curing state or a semi-cured state.

### Sixth Embodiment

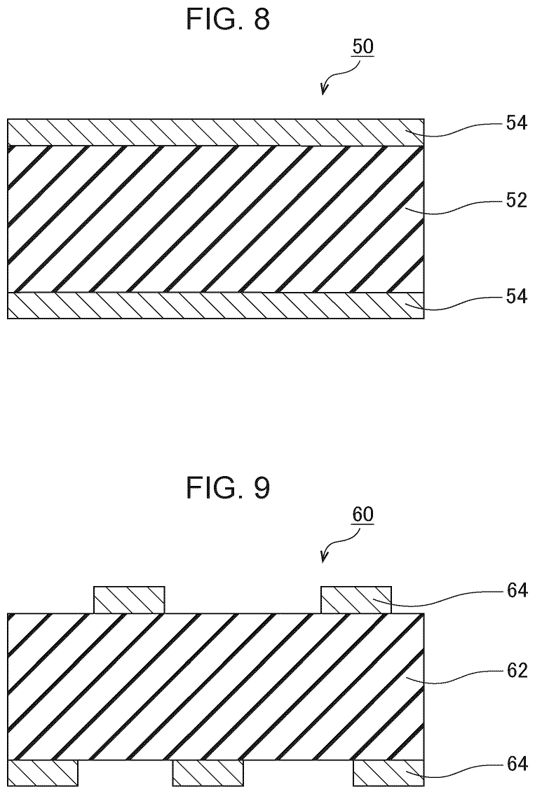

FIG. 6 is a cross-sectional view of a resin-equipped film 30, according to a sixth embodiment. The resin-equipped film 30 includes a resin layer 32 and a support film 34. The resin layer 32 includes the resin composition 20 or a semi-cured product thereof. According to the present embodiment, the resin-equipped film 30 is suitable for insulating layers. The resin layer 32 is supported by the support film 34. In the example of FIG. 6, the support film 34 is located on a surface of the resin layer 32. Note that an additional layer, such as an adhesive layer, may be provided between the resin layer 32 and the support film 34.

The resin layer 32 includes the resin composition 20 of the fourth embodiment, illustrated in FIG. 5, or a semi-cured product thereof and may or may not include a fibrous base material. Fibrous base materials that can be used are the same as the materials for the fibrous base material of the prepreg. When the resin layer 32 is cured, the resin layer 32 transforms into an insulating layer. An example of such an insulating layer is the insulating layer of a wiring board.

The support film 34 may be any support film that is typically used in a resin-equipped film. Examples of the support film 34 include resin films such as polyester films and polyethylene terephthalate films.

### Seventh Embodiment

FIG. 7 is a cross-sectional view of a resin-equipped metal foil 40, according to a seventh embodiment. The resin-equipped metal foil 40 includes a resin layer 42 and a metal foil 44. The resin layer 42 includes the resin composition 20 or a semi-cured product thereof. The resin layer 42 is supported by the metal foil 44. According to the present embodiment, the resin-equipped metal foil 40 is suitable for electronic circuit components, such as wiring boards. In the examples of FIG. 7, the metal foil 44 is located on a surface of the resin layer 42. Note that an additional layer, such as an adhesive layer, may be provided between the resin layer 42 and the metal foil 44.

The resin layer 42 includes the resin composition 20 of the fourth embodiment, illustrated in FIG. 5, or a semi-cured product thereof and may or may not include a fibrous base material. Fibrous base materials that can be used are the same as the materials for the fibrous base material of the prepreg. When the resin layer 42 is cured, the resin layer 42 transforms into an insulating layer. An example of such an insulating layer is the insulating layer of a wiring board.

The metal foil 44 may be any metal foil that is typically used in a resin-equipped metal foil or a metal-clad laminate. Examples of the metal foil include copper foils and aluminum foils.

### Eighth Embodiment

FIG. 8 is a cross-sectional view of a metal-clad laminate 50, according to an eighth embodiment. The metal-clad laminate 50 includes an insulating layer 52 and at least one metal foil 54. According to the present embodiment, the metal-clad laminate 50 is suitable for wiring boards. The insulating layer 52 includes a cured product of the resin composition 20 of the fourth embodiment, illustrated in FIG. 5, or a cured product of the prepreg of the fifth embodiment. The metal foil 54 is located on a surface of the insulating layer 52. In the present embodiment, the metal foil 54 is located on each of the front and back surfaces of the insulating layer 52.

The metal-clad laminate 50 is typically produced with the prepreg of the fifth embodiment. For example, a multi-layer body is formed by stacking 2 to 20 sheets of the prepreg on top of one another. The metal foil is placed on one side or both sides of the multi-layer body of the prepregs, and then, the multi-layer body is heated and pressed. In this manner, the metal-clad laminate 50 can be obtained. Examples of the metal foil 54 include copper foils and aluminum foils.

The production of the metal-clad laminate 50 can be carried out under forming conditions that are typically used in the production of, for example, a laminate or multi-laminate for an electrically insulating material.

### Ninth Embodiment

FIG. 9 is a cross-sectional view of a wiring board 60, according to a ninth embodiment. The wiring board 60 includes an insulating layer 62 and a wiring 64. According to the present embodiment, the wiring board 60 is suitable for use with high frequencies. The insulating layer 62 includes a cured product of the resin composition 20 of the fourth embodiment, illustrated in FIG. 5, or a cured product of the prepreg of the fifth embodiment. The wiring 64 is supported by the insulating layer 62. Specifically, the wiring 64 is located on the insulating layer 62. The wiring 64 can be formed by partially removing the metal foil.

The wiring board 60 provided with the wiring 64, which forms a circuit, on the surface of the insulating layer 62 can be obtained by patterning the metal foil 54 on the surface of the metal-clad laminate 50, illustrated in FIG. 8, by using a method such as etching. That is, the wiring board 60 can be obtained by partially removing the metal foil 54 from the surface of the metal-clad laminate 50 such that a circuit is formed.

An additional layer of the prepreg of the fifth embodiment may be applied onto at least one side of the wiring board 60, and the resultant may be heated and pressed to form another laminate. The metal foil on the surface of the resulting laminate may be patterned to form a wiring. In this case, a multi-laminate wiring board can be obtained.

### EXAMPLES

The present disclosure will be described in detail below with reference to Examples. The Examples are intended to describe the present disclosure and not intended to limit the present disclosure.

### Example 1

The base material used was boron nitride. The boron nitride was h-BN (manufactured by Denka Company Limited, product designation: SGP, average particle size: 18 μm). A dopamine solution (concentration: 23 mg/mL) was obtained by adding dopamine hydrochloride to a Tris-HCl solution that had a pH adjusted to 8.5 and then stirring the solution. 4.5 g of the boron nitride was added to the resulting dopamine solution. The solution was stirred with a magnetic stirrer for 24 hours, with the solution temperature being set at 80° C. Subsequently, the resultant was filtered to afford a solid. The resulting solid was washed with water and subsequently dried. In this manner, particles of boron nitride to which polydopamine was adhered (for convenience, hereinafter referred to as a “polydopamine-modified boron nitride”) were obtained. The presence of the polydopamine was confirmed by a dark brown color exhibited by a surface of the particles of boron nitride.

Next, the polydopamine-modified boron nitride was heat-treated in an electric furnace under the conditions of 100° C. and 24 hours. Accordingly, particles of a composite material of Example 1 were obtained.

### Example 2

Particles of a composite material of Example 2 were obtained in a manner similar to that of Example 1, except that the heat treatment was performed under the conditions of 200° C. and 24 hours.

### Example 3

Particles of a composite material of Example 3 were obtained in a manner similar to that of Example 1, except that the heat treatment was performed under the conditions of 220° C. and 24 hours.

### Example 4

Particles of a composite material of Example 4 were obtained in a manner similar to that of Example 1, except that the heat treatment was performed under the conditions of 240° C. and 24 hours.

### Example 5

Particles of a composite material of Example 5 were obtained in a manner similar to that of Example 1, except that the heat treatment was performed under the conditions of 260° C. and 24 hours.

### Example 6

Particles of a composite material of Example 6 were obtained in a manner similar to that of Example 1, except that the heat treatment was performed under the conditions of 280° C. and 24 hours.

### Example 7

Particles of a composite material of Example 7 were obtained in a manner similar to that of Example 1, except that the heat treatment was performed under the conditions of 300° C. and 24 hours.

### Example 8

Particles of a composite material of Example 8 were obtained in a manner similar to that of Example 1, except that the heat treatment was performed under the conditions of 400° C. and 24 hours.

### Comparative Example 1

Particles of Comparative Example 1 that were used were those of polydopamine-modified boron nitride that were obtained in a manner similar to that of Example 1. That is, in Comparative Example 1, the polydopamine-modified boron nitride was used without being heat-treated.

The particles obtained in the Examples and the Comparative Example described above were each evaluated for the dielectric loss tangent, the infrared absorption spectrum, and the N 1s spectrum.

### Measurement of Dielectric Loss Tangent

The particles obtained in each of Examples 1 to 8 and Comparative Example 1 were subjected to a measurement of the dielectric loss tangent at a frequency of 1 GHz. The measuring device used was a cavity resonator (MS46122B, manufactured by AET, Inc.).

The measurement was performed to determine whether the dielectric loss tangent was good. When the measured value was less than or equal to 0.0040, it was determined that the dielectric loss tangent was good. When the measured value was less than or equal to 0.0030, it was determined that the dielectric loss tangent was particularly good.

### Measurement of Infrared Absorption Spectrum

The particles obtained in each of Examples 1 to 8 and Comparative Example 1 were subjected to a measurement of the infrared absorption spectrum, which was performed with an FT-IR spectrometer (Nicolet 6700, manufactured by Thermo Fisher Scientific, Inc.) in a diffuse reflection mode over wavenumbers of 400 cm⁻¹ to 4000 cm⁻¹. From the obtained infrared absorption spectra, the H_{B}/H_{A} was determined in the manner described above.

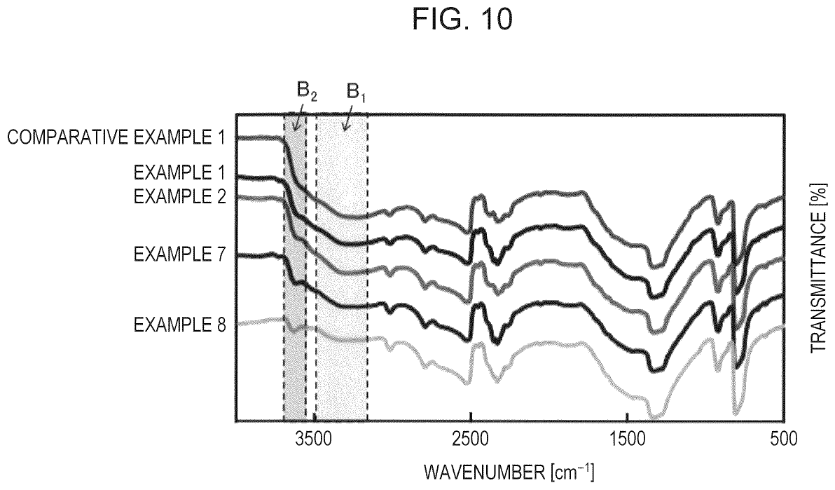

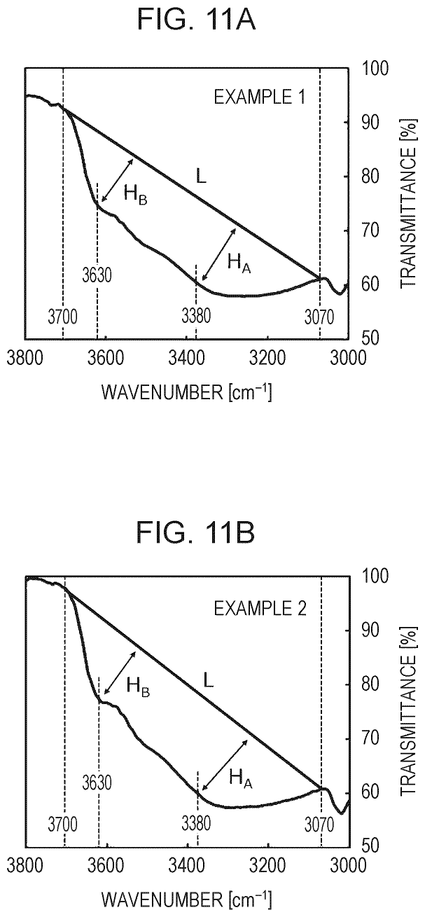

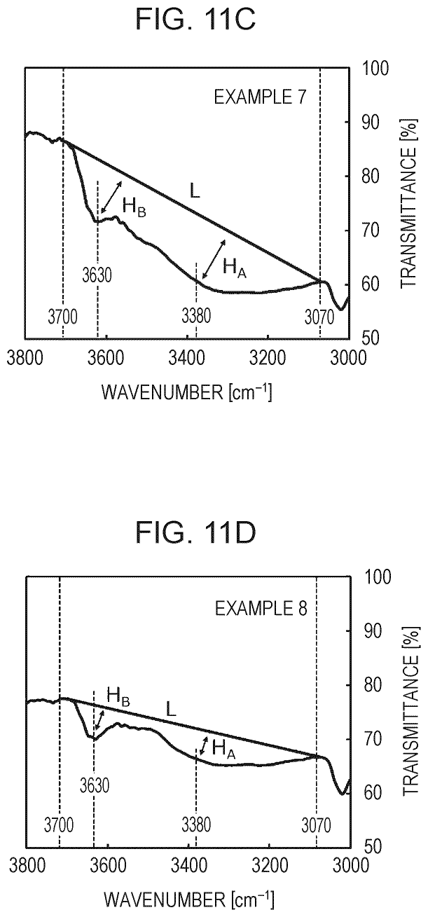

FIG. 10 shows the infrared absorption spectra of Examples 1, 2, 7, and 8 and Comparative Example 1. In FIG. 10, the vertical axis represents the transmittance (%), and the horizontal axis represents the wavenumber (cm⁻¹). Note that in FIG. 10, in order to facilitate the comparison between the infrared absorption spectra, the scale on the vertical axis has been shifted so that the spectra can be shown in an overlapping manner, and the scale on the vertical axis is not illustrated. FIGS. 11A to 11D are enlarged views of main parts of the infrared absorption spectra of Examples 1, 2, 7, and 8, respectively. As illustrated in FIGS. 11A to 11D, as the heat treatment temperature increases, the H_{B} increases relative to the H_{A}. That is, as the heat treatment temperature increases, the value calculated as H_{B}/H_{A} increases.

Table 1 shows the dielectric loss tangent and the H_{B}/H_{A} of Examples 1 to 8 and Comparative Example 1, together with the heat treatment temperature.

TABLE 1

| | Heat Treatment | Dielectric Loss | |
|---|---|---|---|
| | Temperature | Tangent | H_{B}/H_{A} |
| Example 1 | 100° C. | 0.00351 | 0.674 |
| Example 2 | 200° C. | 0.00247 | 0.702 |
| Example 3 | 220° C. | 0.00231 | 0.726 |
| Example 4 | 240° C. | 0.00240 | 0.758 |
| Example 5 | 260° C. | 0.00249 | 0.787 |
| Example 6 | 280° C. | 0.00267 | 0.803 |
| Example 7 | 300° C. | 0.00284 | 0.815 |
| Example 8 | 400° C. | 0.00305 | 1.017 |
| Comparative | No Heat | 0.00717 | 0.654 |
| Example 1 | Treatment | | |

### Measurement of N 1s Spectrum

The particles obtained in each of Examples 1, 2, 7, and 8 and Comparative Example 1 were subjected to a measurement of the N 1s spectrum, which was performed with an XPS spectrometer (PHI 5000 VersaProbe, manufactured by Ulvac-Phi, Inc.). The light source used was monochromatic Al Kα radiation (1486.6 eV). From the obtained N 1s spectrum, the ratio R₁ was determined in the manner described above.

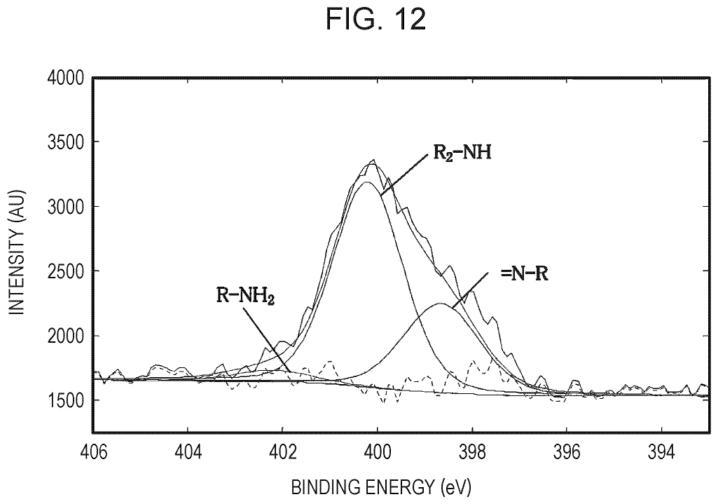

FIG. 12 is a graph showing the N 1s spectrum of Example 2. In FIG. 12, the vertical axis represents an intensity (AU) of the spectrum, and the horizontal axis represents a binding energy (eV).

Table 2 shows the ratio R₁ of Examples 1, 2, 7, and 8 and Comparative Example 1, together with the heat treatment temperature.

TABLE 2

| | Heat Treatment | Ratio |
|---|---|---|
| | Temperature | R₁ (%) |
| Example 1 | 100° C. | 4.3 |
| Example 2 | 200° C. | 3.9 |
| Example 7 | 300° C. | 5.8 |
| Example 8 | 400° C. | 5.2 |
| Comparative | No Heat | 8.8 |
| Example 1 | Treatment | |

### Discussion

As can be seen from Table 1, Examples 1 to 8, which had ratios H_{B}/H_{A} that satisfied 0.66≤H_{B}/H_{A}≤1.1 in the infrared absorption spectra, had dielectric loss tangents of 0.0040 or less, which were good values. Examples 2 to 7, which had ratios H_{B}/H_{A} that satisfied 0.70≤H_{B}/H_{A}≤0.90, had dielectric loss tangents of 0.0030 or less, which were particularly good values.

As can be seen from Table 2, Examples 1 to 8, which had ratios R₁ that satisfied 3.0%≤R₁≤7.0% in the N 1s spectra, had dielectric loss tangents of 0.0040 or less, which were good values.

Although boron nitride was used as the base material in the Examples, the boron nitride may be replaced with a different material, such as aluminum nitride, silicon nitride, aluminum oxide, magnesium oxide, or silica. It is presumed that in these cases, a reduction in the dielectric loss tangent is also achieved. A reason for this presumption is that the composite material of the present disclosure is one in which a reduction in the dielectric loss tangent has been achieved by reducing the amount of hydrogen-bond-forming hydroxy groups that are present in the coating film made of polydopamine and reducing the amount of hydroxyl radicals that are present in the coating film made of polydopamine.

While the present disclosure has been appropriately and sufficiently described through the embodiments presented above, for the purpose of representation of the present disclosure, those skilled in the art should be aware that the above-described embodiments can be easily changed and/or modified. Accordingly, changed embodiments or modified embodiments that are implemented by those skilled in the art are deemed to be encompassed by the scope of the claims described in “WHAT IS CLAIMED IS”, as long as the changed embodiments or modified embodiments are not at a level that departs from the scope of the claims.

The composite material of the present disclosure enables the realization of a filler having a reduced dielectric loss tangent and, therefore, is suitable, for example, for applications such as wiring boards of electronic devices that are used in high-capacity communications.

What is claimed is:

1. A composite material comprising:
a base material; and
polydopamine adhered to the base material, wherein
in an infrared absorption spectrum of the base material to which the polydopamine is adhered, the infrared absorption spectrum being obtained by Fourier transform infrared spectroscopy, a ratio H_{B}/H_{A} satisfies 0.66≤H_{B}/H_{A}≤1.1, where
in the infrared absorption spectrum, a baseline is defined as a straight line connecting a measured point obtained at 3070 cm⁻¹ to a measured point obtained at 3700 cm⁻¹,
H_{A} represents a perpendicular distance from a measured point obtained at 3380 cm⁻¹ of the infrared absorption spectrum to the baseline, and
H_{B} represents a perpendicular distance from a measured point obtained at 3630 cm⁻¹ of the infrared absorption spectrum to the baseline.

2. The composite material according to claim 1, wherein the ratio H_{B}/H_{A} satisfies 0.70≤H_{B}/H_{A}≤0.90.

3. The composite material according to claim 1, wherein, in a N 1s spectrum of the composite material, the N 1s spectrum being obtained by X-ray photoelectron spectroscopy, a ratio of an area of a peak corresponding to a nitrogen atom of a primary amino group to an area of an entirety of the N 1s spectrum is greater than or equal to 3.0% and less than or equal to 7.0%.

4. The composite material according to claim 1, wherein the base material comprises at least one selected from the group consisting of boron nitride, aluminum nitride, silicon nitride, aluminum oxide, magnesium oxide, and silica.

5. The composite material according to claim 4, wherein the base material comprises boron nitride.

6. A filler comprising the composite material according to claim 1.

7. A resin composition comprising the filler according to claim 6.

8. A prepreg comprising the resin composition according to claim 7 or comprising a semi-cured product of the resin composition.

9. A resin-equipped film comprising:
a resin layer comprising the resin composition according to claim 7 or comprising a semi-cured product of the resin composition; and
a support film.

10. A resin-equipped metal foil comprising:
a resin layer comprising the resin composition according to claim 7 or comprising a semi-cured product of the resin composition; and
a metal foil.

11. A metal-clad laminate comprising:
an insulating layer comprising a cured product of the resin composition according to claim 7 or comprising a cured product of a prepreg, the prepreg comprising the resin composition or comprising a semi-cured product of the resin composition; and
a metal foil.

12. A wiring board comprising:
an insulating layer comprising a cured product of the resin composition according to claim 7 or comprising a cured product of a prepreg, the prepreg comprising the resin composition or comprising a semi-cured product of the resin composition; and
a wiring.

13. A method for producing a base material to which polydopamine is adhered, the method comprising:
causing polydopamine to be adhered to a surface of a base material; and
heating the base material and the polydopamine adhered to the surface.

14. The method for producing a base material to which polydopamine is adhered according to claim 13, wherein the heating comprises heating the base material and the polydopamine at a temperature of greater than or equal to 100° C. and less than or equal to 400° C.

15. The method for producing a base material to which polydopamine is adhered according to claim 13, wherein the heating comprises heating the base material and the polydopamine at a temperature of greater than or equal to 200° C. and less than or equal to 300° C.
